(19) United States
(12) Patent Application Publication
(10) Pub. No.: US 2026/0365878 A1
(43) Pub. Date: Nov. 19, 2026

(54) POLISHING COMPOSITION AND USE THEREOF

(71) Applicant: ANJI MICROELECTRONICS TECHNOLOGY (SHANGHAI) CO., LTD., Pudong New Area, Shanghai (CN)

(72) Inventors: Pengyu XU, Shanghai (CN); Shoutian LI, Shanghai (CN); Xingping WANG, Shanghai (CN); Zhangzheng JIA, Shanghai (CN)

(21) Appl. No.: 19/138,590

(22) PCT Filed: Dec. 12, 2023
(86) PCT No.: PCT/CN2023/138015

§ 371 Date: Jun. 12, 2025

(30) Foreign Application Priority Data
Dec. 13, 2022 (CN) 202211595027.0

(51) Int. Cl. C09G 1/02; C09K 3/14

(52) U.S. Cl. CPC C09G 1/02; C09K 3/1409

(57) ABSTRACT

The invention provides a polishing composition comprising ceria abrasive particles, an anionic surfactant, a cationic polymer, and a nonionic surfactant. The polishing composition provided by the present invention has good stability, is easy to store and can be used in practice; and by adjusting the addition of different anionic molecules, it can achieve the purpose of controlling different butterfly-shaped sizes, thereby meeting the application requirements of different structures.

### TECHNICAL FIELD

The present invention relates to the field of chemical mechanical polishing, to a polishing composition and its application.

### BACKGROUND

During the process of fabricating chips, the shallow trench isolation structure (STI) is the most common type. Generally, silicon nitride and polycrystalline silicon are used as the stop layers. It is necessary to quickly remove the surface oxide layer during the polishing process. However, after the silicon nitride or polycrystalline silicon layer is exposed, it can protect the silicon nitride or polycrystalline silicon layer. That is to say, the polishing solution has almost no polishing rate for the stop layer. For the traditional application of STI, a very small butterfly shape is required to ensure sufficient polishing time. However, with the current trend of complex integrated circuit design and multi-layer structures, the polishing solution needs to be able to meet the requirements for different butterfly shapes (dishing sizes). For example, some new design structures require very high butterfly shapes to meet the subsequent processing needs. To meet this requirement, there is an increasing demand for high-butterfly-shape polishing solutions.

Therefore, there is an urgent need in this field for a polishing solution that can effectively control the size of the disc-shaped areas on the polished wafer surface, in order to meet various polishing requirements.

### DESCRIPTION

To solve the technical problem of having different heights of concave shapes on the polished surface of the wafer, this invention provides a polishing composition that can be used for polishing silicon oxide, which can effectively reduce the surface topography and polishing effect of the polished wafer.

In particular, the invention provides a polishing composition comprising ceria abrasive particles, a cationic polymer, an anionic surfactant, and a nonionic surfactant.

Preferably, the cerium oxide abrasive particles are colloidal cerium oxide particles.

Preferably, the anionic surfactant is selected from phosphate compound or carboxylate anionic polymer.

Preferably, the phosphate compound is selected from one or more of phosphoric acid, potassium phosphate, dihydrogen phosphate potassium, and Nitrilotrimethylene Triphosphonic Acid (ATMP).

Preferably, the anionic polymer is polyacrylic ammonium salt and copolymers thereof.

Preferably, the cationic polymer is polyquaternium.

Preferably, the cationic polymer is selected from one or more of Polyquaternium 2, Polyquaternium 6, Polyquaternium 7, Polyquaternium 28, Polyquaternium 37.

Preferably, the non-ionic surfactant is polyethylene glycol having molecular weight of less than 10000.

Preferably, the pH value of the polishing composition is 2 to 7.

In another aspect of the invention, there is provided the use of a polishing composition as described in any of the above to polish silica.

Compared with the existing technologies, the polishing composition in this invention has the following beneficial effects:
1. It has a relatively stable polishing effect, is easy to store the polishing solution, and is also convenient for actual use.
2. When the polishing composition of the present invention is used for polishing the patterned wafer, by adjusting the addition of different anionic surfactants, it is possible to control the size of the polished disc. Specifically, when using phosphate compounds as the anionic surfactant, a larger disc shape can be obtained; while when using carboxylate anion polymers as the anionic surfactant, a smaller disc shape can be achieved. Thus, this enables the control of different disc sizes, thereby meeting the actual application requirements of different structures.

### EMBODIMENTS

The advantages of the invention will be further explained in detail with reference to the following embodiments.

### Embodiment 1

After mixing 1 kg of cerium oxide particles, 40 g of the ammonium polyacrylate salt, and 8740 g of deionized water, dispersion was carried out with stirring and sonication for 30 minutes. Subsequently 220 g of Polyquaternium 7 was added, followed by dilution to 0.2% cerium oxide content, then 1000 ppm polyethylene glycol (molecular weight 10,000) was added, and the pH was adjusted to 4.8 using nitric acid.

### Embodiment 2

After mixing 1 kg of cerium oxide particles, 60 g of polyaspartic acid and 8720 g of deionized water, the dispersion was carried out with stirring and sonication for 30 minutes. Subsequently 220 g of Polyquaternium 37 was added, followed by dilution to 0.2% Cerium Oxide content, followed by addition of 1000 ppm Polyethylene Glycol (molecular weight 10,000) and the pH was adjusted to 4.8 using nitric acid.

### Embodiment 3

After mixing 1 kg of cerium oxide particles, 60 g of dipotassium phosphate and 8720 g of deionized water, the dispersion was carried out with stirring and sonication for 30 minutes. Subsequently 220 g of Polyquaternium 7 was added, followed by dilution to 0.2% cerium oxide content, followed by addition of 1000 ppm polyethylene glycol (molecular weight 10,000) and the pH was adjusted to 4.8 using nitric acid.

### Embodiment 4

After mixing 1 kg of cerium oxide particles, 30 g of Nitrilotrimethylene Triphosphonic Acid (ATMP) and 8750 g of deionized water, the dispersion was carried out with stirring and sonication for 30 minutes. Followed by addition of 220 g of Polyquaternium 7, followed by dilution to 0.2% Cerium Oxide content, followed by addition of 1000 ppm Polyethylene Glycol (molecular weight 10,000) and the pH was adjusted to 4.8 using nitric acid.

### Comparative Embodiment 1

Dilute 1 kg of cerium oxide particles to a 0.2% cerium oxide concentration, then add 1000 ppm polyethylene glycol (molecular weight 10,000), and adjust the pH to 4.8 using nitric acid.

### Comparative Embodiment 2

After mixing 1 kg of cerium oxide particles, 40 g of the ammonium polyacrylate salt, and 8740 g of deionized water, dispersion was carried out with stirring and sonication for 30 minutes. Subsequently 220 g of Polyquaternium 7 was added, followed by dilution to 0.2% cerium oxide content, followed by addition of 1000 ppm polyethylene glycol (molecular weight 10,000) and the pH was adjusted to 9.0 using nitric acid.

Polishing object: TEOS blank wafers and patterned wafers (with TEOS films deposited with different line/slot structures), the measured line width/slot width of the patterned TEOS is 100 um/100 um.

Polishing equipment: Mirra polishing machine; IC1010 polishing pad; NanoSpec film thickness measurement system (NanoSpec6100-300, Shanghai Nanospec Technology Corporation).

Polishing conditions: The spindle speeds of Platten and Carrier are 93 rpm and 87 rpm respectively, the polishing pressure is 3.0 psi, and the flow rate of the polishing solution is 150 mL/min.

Polishing Step: The TEOS blank wafer and graphic wafer were subjected to a polishing process using the above prepared polishing solution using the above-described polishing apparatus and polishing conditions, respectively. Starting at 3 mm from the wafer edge, 49 points were measured at equal spacing on the diameter line and their polishing rates were tested separately, thus, the polishing rate for each polishing liquid was an average of the polishing rates over 49 points. The polishing results were measured as shown in Table 1. Note: the polishing composition of Comparative Embodiment 2 produced precipitation when adjusted for pH and was not further tested, so the results of the testing of Comparative Embodiment 2 are not shown in Table 1.

TABLE 1
Components and Content of Embodiments 1-4 and Comparative
Embodiments 1, and Polishing Test Results

| | | | | Polishing | Polishing | Dishing |
|---|---|---|---|---|---|---|
| | | | | rate of | rate of | Growth Rate |
| | Anion | Cation | Polyethylene | SiO2 | polysilicon | (Å/min, |
| | (ppm) | (ppm) | glycol (ppm) | (Å/min) | (Å/min) | 100 um*100 um) |
| Embodiment | 8 | 44 | 1000 | 5436 | 5 | 1200 |
| 1 | | | | | | |
| Embodiment | 12 | 44 | 1000 | 5550 | 7 | 1260 |
| 2 | | | | | | |
| Embodiment | 12 | 44 | 1000 | 4816 | 7 | 1812 |
| 3 | | | | | | |
| Embodiment | 6 | 44 | 1000 | 5819 | 4 | 1700 |
| 4 | | | | | | |
| Comparative | — | — | 1000 | 4797 | 15 | 2022 |
| Embodiment | | | | | | |
| 1 | | | | | | |

As can be seen from Table 1, Embodiments 1-4 show that after adding the corresponding anionic surfactants and polyethylene glycol, sufficient polishing rate can still be maintained, and the polycrystalline silicon can be effectively inhibited. When using the same concentration of polyethylene glycol, by using different types of anionic surfactants, the size of the butterfly shape can be effectively adjusted to meet different application scenarios. Specifically, when a larger butterfly shape is required for polishing, phosphoric acid compounds are used as anionic surfactants; when a smaller butterfly shape is required for polishing, carboxylate anionic polymers are used as anionic surfactants. At the same time, regardless of which anionic surfactant is added, it can effectively increase the polishing rate of the polishing composition for silicon dioxide and reduce the polishing rate for polycrystalline silicon.

In summary, by using the anionic surfactants and polycrystalline silicon inhibitors as defined in this application, the polishing rate can be effectively increased, the polishing rate of silicon oxide can be guaranteed, it can stop on the polycrystalline silicon, and the size of the butterfly shape can be significantly adjusted, thus enabling flexible application in different structural requirements.

Although the above specific embodiments of the present invention have been described in detail, they are only examples, and the present disclosure is limited to the embodiments described above. For those skilled in the art, any equivalent modification and substitution to the present invention is also covered in the present invention. Therefore, all these equivalent changes and modifications made without departing from the spirit and scope of the invention should be covered within the scope of the present invention.

1. A polishing composition, comprising cerium oxide abrasive particles, cationic polymer, anionic surfactant, and nonionic surfactant.

2. The polishing composition according to claim 1, wherein, the cerium oxide abrasive particles are colloidal cerium oxide particles.

3. The polishing composition according to claim 1, wherein, the anionic surfactant is selected from phosphate compounds or carboxylate anion polymers.

4. The polishing composition according to claim 3, wherein, the phosphate compound is selected from one or more of phosphoric acid, potassium phosphate, dihydrogen phosphate potassium, and Nitrilotrimethylene Triphosphonic Acid (ATMP).

5. The polishing composition according to claim 3, wherein, the carboxylate anion polymer is ammonium polyacrylate salts and copolymers thereof.

6. The polishing composition according to claim 1, wherein, the cationic polymer is a polyquaternary ammonium salt.

7. The Polishing composition according to claim 6, wherein the cationic polymer is selected from one or more of Polyquaternium 2, Polyquaternium 6, Polyquaternium 7, Polyquaternium 28, Polyquaternium 37.

8. The polishing composition according to claim 1, wherein, non-ionic surfactant is polyethylene glycol having molecular weight of less than 10000.

9. The polishing composition according to claim 1, wherein, the pH value of the polishing composition is 2 to 7.

10. An application of the polishing composition as described in claim 1 for polishing silica.
